(19) United States
(12) Patent Application Publication
(10) Pub. No.: US 2026/0115674 A1
(43) Pub. Date: Apr. 30, 2026

(54) SUBSTRATE PROCESSING APPARATUS AND SUBSTRATE PROCESSING METHOD

(71) Applicant: SEMES CO., LTD., Cheonan-si (KR)

(72) Inventor: Sung Pil KIM, Hwaseong-si (KR)

(73) Assignee: SEMES CO., LTD., Cheonan-si (KR)

(21) Appl. No.: 19/365,520

(22) Filed: Oct. 22, 2025

(30) Foreign Application Priority Data
Oct. 25, 2024 (KR) 10-2024-0147871

(51) Int. Cl. B01F 23/43; B01F 23/45; B01F 25/50; B01F 33/45; B01F 35/90; B01F 101/58; B08B 3/08; B08B 3/10; H01L 21/67

(52) U.S. Cl. CPC B01F 23/43; B01F 23/45; B01F 25/50; B01F 33/45; B01F 35/90; B08B 3/08; B08B 3/102; H10P 72/0404; B01F 2035/99; B01F 2101/58

(57) ABSTRACT

Provided is an apparatus for processing a substrate, the apparatus including: a liquid treating chamber for liquid-treating a substrate; and a liquid supply unit for supplying a treatment liquid to the liquid treating chamber. The liquid supply unit includes: a supply tank for storing the treatment liquid therein; a circulation line connected to the supply tank to circulate the treatment liquid; and a liquid supply line having an opening/closing valve installed and branching from the circulation line to supply the treatment liquid to the liquid treating chamber. The supply tank is provided with a first stirrer that configured to apply flow pressure to the treatment liquid in the supply tank.

### CROSS-REFERENCE TO RELATED APPLICATION

This application claims priority to and the benefit of Korean Patent Application No. 10-2024-0147871 filed in the Korean Intellectual Property Office on Oct. 25, 2024, the entire contents of which are incorporated herein by reference.

### TECHNICAL FIELD

The present invention relates to an apparatus for processing a substrate and a method of processing a substrate, and more specifically, a substrate processing apparatus and a substrate processing method that are capable of improving the supply efficiency of a treatment liquid.

### BACKGROUND ART

To manufacture a semiconductor device or liquid crystal display, various processes, such as photolithography, etching, ashing, ion implantation, and deposition, are performed on a substrate. In addition, when any one process is performed, a process of cleaning the substrate with a treatment liquid is performed before the next process is performed.

In general, a cleaning device performing the above cleaning process has a liquid treating chamber and a liquid supply unit. The liquid supply unit has a supply tank in which a treatment liquid used for cleaning is stored. A circulation line is connected to the supply tank, and various components, such as a pump, a heater, a filter, and a valve, are installed in the circulation line. In addition, the liquid supply line for supplying the treatment liquid to the liquid treating chamber is installed to branch from the circulation line, and an opening/closing valve is installed in the liquid supply line.

When the temperature and concentration of the treatment liquid are adjusted while circulating the treatment liquid through the circulation line, it takes a lot of time and accordingly, the process efficiency is lowered.

During the circulation of the treatment liquid through the circulation line, if an abnormality occurs in the component installed in the circulation line, the operation of the pump is stopped, the liquid is not circulated, and the treatment liquid is stored stagnant in the supply tank.

In addition, when the liquid is exchanged inside the supply tank, the liquid discharged from the supply tank is stored in a drain box, and the temperature and concentration of the hot liquid are lowered by the diluted liquid. However, it takes a lot of time for the liquid to have the lowered temperature and concentration uniformly required as a whole in the drain box.

However, when the treatment liquid is a high viscosity liquid, such as sulfuric acid, the treatment liquid is agglomerated when the treatment liquid does not flow and is stagnated. In this case, even though the components installed in the circulation line are replaced, the treatment liquid in the supply tank cannot be used if it takes a lot of time. Therefore, the treatment liquid in the supply tank needs to be discarded and the substrate must be processed with a new treatment liquid. Therefore, the amount of waste of the treatment liquid is large, and it takes a lot of time to replenish the new treatment liquid into the supply tank and heat the treatment liquid to a set temperature.

### SUMMARY OF THE INVENTION

The present invention has been made in an effort to provide a substrate processing apparatus and a substrate processing method capable of rapidly adjusting the temperature and concentration of a treatment liquid in a supply tank.

The present invention has also been made in an effort to provide a substrate processing apparatus and a substrate processing method for preventing a treatment liquid from being aggregated even when the treatment liquid in a supply tank is not circulated through a circulation line.

The present invention has also been made in an effort to provide a substrate processing apparatus and a substrate processing method capable of reducing the amount of disposal of a treatment liquid.

The present invention has also been made in an effort to provide a substrate processing apparatus and a substrate processing method capable of supplying a treatment liquid to a liquid treating chamber immediately when a pump is restarted after an operation of the pump is stopped due to an abnormality in a component installed in a circulation line.

The objectives of the present disclosure are not limited thereto and other objectives not stated herein may be clearly understood by those skilled in the art from the following description.

An exemplary embodiment of the present disclosure, an apparatus for processing a substrate, the apparatus comprising: a liquid treating chamber for liquid-treating a substrate; and a liquid supply unit for supplying a treatment liquid to the liquid treating chamber, wherein the liquid supply unit includes: a supply tank for storing the treatment liquid therein; a circulation line connected to the supply tank to circulate the treatment liquid; and a liquid supply line having an opening/closing valve installed and branching from the circulation line to supply the treatment liquid to the liquid treating chamber, and the supply tank may be provided with a first stirrer that configured to apply flow pressure to the treatment liquid therein.

According to the exemplary embodiment of the present invention, the apparatus may further include a controller for controlling the liquid supply unit, wherein the controller controls the first stirrer to allow the treatment liquid in the supply tank to flow while the circulation of the treatment liquid is stopped.

According to the exemplary embodiment of the present invention, the apparatus may further include a controller for controlling the liquid supply unit, wherein the controller controls the first stirrer to allow the treatment liquid in the supply tank to flow while the treatment liquid is circulated through the circulation line.

According to the exemplary embodiment of the present invention, wherein the first stirrer may be a magnetic stirrer.

According to the exemplary embodiment of the present invention, wherein the first stirrer may includes: an electromagnet installed outside the supply tank and configured to generate flow pressure by applying a current to the treatment liquid in the supply tank; and a power supply device for supplying a current to the electromagnet.

According to the exemplary embodiment of the present invention, wherein the liquid supply unit includes: a discharge pipe for discharging the treatment liquid in the supply tank; and a drain box connected to the discharge pipe, and a second stirrer may be installed in the drain box to provide flow pressure to the treatment liquid in the drain box.

According to the exemplary embodiment of the present invention, the apparatus may further include a controller for controlling the liquid supply unit, wherein the controller may controls the second stirrer to allow the treatment liquid in the drain box to flow when the treatment liquid flows from the supply tank to the drain box.

According to the exemplary embodiment of the present invention, wherein a diluent supply line may be connected to the drain box to supply a diluent at room temperature or a temperature lower than room temperature to the drain box.

According to the exemplary embodiment of the present invention, wherein the second stirrer may be a magnetic stirrer.

An exemplary embodiment of the present disclosure, a method of processing a substrate, the method comprising: an adjustment operation of adjusting a temperature and a concentration of a treatment liquid stored in a supply tank; and a liquid treatment operation of supplying the temperature and concentration adjusted treatment liquid to a liquid treating chamber through a liquid supply line branching from the circulation line, after the adjustment operation, wherein in the adjustment operation, the treatment liquid flows by a first stirrer installed in the supply tank while the treatment liquid may be circulated.

According to the exemplary embodiment of the present invention, wherein in the adjustment operation, the treatment liquid may be heated using a heater installed in the supply tank while circulating the treatment liquid.

According to the exemplary embodiment of the present invention, wherein in the circulation stop operation, the treatment liquid in the supply tank flows using the first stirrer may installed in the supply tank.

According to the exemplary embodiment of the present invention, wherein in the adjustment operation, as a difference between a set temperature and a temperature of the treatment liquid increases, a flow rate of the treatment liquid in the supply tank may increases.

According to the exemplary embodiment of the present invention, the apparatus may further include a circulation stop operation of stopping operation when an abnormality occurs in a liquid supply unit including the supply tank, the circulation line, and the liquid supply line, wherein when the abnormality of the liquid supply unit is resolved and the treatment liquid is reusable, the adjustment operation may be performed again.

According to the exemplary embodiment of the present invention, wherein the first stirrer may provides flow pressure to the treatment liquid by magnetic force.

According to the exemplary embodiment of the present invention, the apparatus may further include a liquid exchange operation of exchanging the treatment liquid in the supply tank, the liquid exchange operation being performed when the treatment liquid is not reusable after the circulation stop operation.

According to the exemplary embodiment of the present invention, wherein in the liquid exchange operation, the treatment liquid in the supply tank is discharged to a drain box through a drain line, and the treatment liquid in the drain box flows by a second stirrer may installed in the drain box.

According to the exemplary embodiment of the present invention, wherein the second stirrer may provides flow pressure to the treatment liquid by magnetic force.

According to the exemplary embodiment of the present invention, wherein the treatment liquid may be a mixture of sulfuric acid (H₂SO₄), hydrogen peroxide (H₂O₂), and pure water (H₂O).

An exemplary embodiment of the present disclosure, an apparatus for processing a substrate, the apparatus comprising: a liquid treating chamber for liquid-treating a substrate; and a liquid supply unit for supplying a treatment liquid to the liquid treating chamber, wherein the liquid supply unit includes: a supply tank for storing the treatment liquid therein; a circulation line connected to the supply tank to circulate the treatment liquid; a liquid supply line having an opening/closing valve installed and branching from the circulation line to supply the treatment liquid to the liquid treating chamber; a discharge pipe for discharging the treatment liquid in the supply tank; and a drain box connected to the discharge pipe, and the supply tank is provided with a first stirrer that configured to apply flow pressure to the treatment liquid in the supply tank and is provided as a magnetic stirrer, the first stirrer includes: an electromagnet which is installed outside the supply tank and to which current is applied to provide flow pressure to the treatment liquid in the supply tank; and a power supply device for applying a current to the electromagnet, and the drain box may be provided with a second stirrer that provides flow pressure to the treatment liquid in the drain box.

According to the exemplary embodiment of the present invention, it is possible to rapidly adjust the temperature and concentration of a treatment liquid in a supply tank.

According to the exemplary embodiment of the present invention, it is possible to prevent a treatment liquid from being aggregated even when the treatment liquid in a supply tank is not circulated through a circulation line.

According to the exemplary embodiment of the present invention, it is possible to reduce the amount of disposal of a treatment liquid.

According to the exemplary embodiment of the present invention, it is possible to supply a treatment liquid to a liquid treating chamber immediately when a pump is restarted after an operation of the pump is stopped due to an abnormality in a component installed in a circulation line.

Effects of the present disclosure are not limited to those described above and effects not stated above will be clearly understood to those skilled in the art from the specification and the accompanying drawings.

### BRIEF DESCRIPTION OF THE DRAWINGS

The various features and advantages of the non-limiting exemplary embodiment of the present specification may become more apparent by reviewing the detailed description together with the accompanying drawings. The accompanying drawings are provided for illustrative purposes only and should not be construed as limiting the scope of claims. The accompanying drawings are not considered to be drawn to scale unless explicitly stated. For clarity, the various dimensions of the drawings may have been exaggerated.

FIG. 1 is a top plan view schematically illustrating a substrate processing apparatus according to an exemplary embodiment of the present invention.

FIG. 2 is a diagram schematically illustrating a liquid treating chamber of FIG. 1 according to an exemplary embodiment.

FIG. 3 is a diagram schematically illustrating a configuration of a liquid supply unit for supplying a treatment liquid to a nozzle of the liquid treating chamber.

FIG. 4 is a flowchart schematically illustrating a process of supplying a treatment liquid by the liquid supply unit of FIG. 3.

FIG. 5 is a diagram schematically illustrating the liquid supply unit in an adjustment operation of FIG. 4.

FIG. 6 is a diagram schematically illustrating the liquid supply unit in a liquid treatment operation of FIG. 4.

FIG. 7 is a diagram schematically illustrating the liquid supply unit in a circulation operation of FIG. 4.

FIG. 8 is a diagram schematically illustrating the liquid supply unit in the liquid exchange operation of FIG. 4.

FIG. 9 is a diagram schematically illustrating a modified example of the liquid supply unit of FIG. 3.

### DETAILED DESCRIPTION

Hereinafter, an exemplary embodiment of the present invention will be described more fully hereinafter with reference to the accompanying drawings, in which exemplary embodiments of the invention are illustrated. However, the present invention may be variously implemented and is not limited to the following exemplary embodiments. In the following description of the present invention, a detailed description of known functions and configurations incorporated herein is omitted to avoid making the subject matter of the present invention unclear. In addition, the same reference numerals are used throughout the drawings for parts having similar functions and actions.

Unless explicitly described to the contrary, the word “include” will be understood to imply the inclusion of stated elements but not the exclusion of any other elements. It will be appreciated that terms “including” and “having” are intended to designate the existence of characteristics, numbers, operations, operations, constituent elements, and components described in the specification or a combination thereof, and do not exclude a possibility of the existence or addition of one or more other characteristics, numbers, operations, operations, constituent elements, and components, or a combination thereof in advance.

Singular expressions used herein include plurals expressions unless they have definitely opposite meanings in the context. Accordingly, shapes, sizes, and the like of the elements in the drawing may be exaggerated for clearer description.

An expression, “and/or” includes each of the mentioned items and all of the combinations including one or more of the items. Further, in the present specification, “connected” means not only when member A and member B are directly connected, but also when member A and member B are indirectly connected by interposing member C between member A and member B.

Embodiments of the present disclosure may be modified in various ways and the scope of the present disclosure should not be construed as being limited to the embodiments to be described below. Embodiments are provided to more completely explain the present disclosure to those skilled in the art. Accordingly, the shapes of the components shown in the figures are exaggerated to enhance clearer description.

An apparatus according to the present exemplary embodiment is described as being used to store and supply a treatment liquid used to clean a substrate in a tank, but this is for convenience of explanation, and the present invention may also be applied to other processes, such as photolithography processes, using the treatment liquid for substrates, such as semiconductor wafers, masks, or flat panel displays.

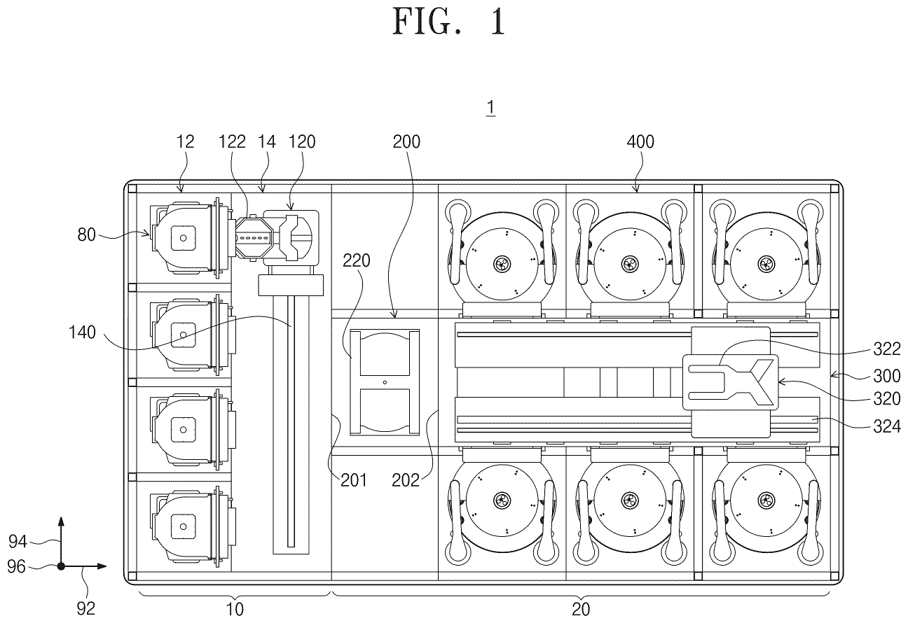

Hereinafter, exemplary embodiments of the present invention will be described with reference to FIGS. 1 to 9.

FIG. 1 is a top plan view schematically illustrating a substrate processing apparatus according to an exemplary embodiment of the present invention.

Referring to FIG. 1, a substrate processing apparatus 1 includes an index module 10, a treating module 20, and a controller 2. The index module 10 and the treating module 20 are disposed along one direction. Hereinafter, the direction in which the index module 10 and the treating module 20 are disposed is referred to as a first direction 92, and when viewed from above, a direction perpendicular to the first direction 92 is referred to as a second direction 94, and a direction perpendicular to both the first direction 92 and the second direction 94 is referred to as a third direction 96.

The index module 10 transfers a substrate W from a container 80 in which the substrate W is accommodated to the treating module 20, and makes the substrate W, which has been completely processed in the treating module 20, be accommodated in the container 80. A longitudinal direction of the index module 10 is provided in the second direction 94. The index module 10 includes a load port 12 and an index frame 14. Based on the index frame 14, the load port 12 is located at a side opposite to the treating module 20. The containers 80 in which the substrates W are accommodated are placed on the load ports 12. The load port 12 may be provided in plural, and the plurality of load ports 12 may be disposed in the second direction 94.

An index robot 120 is provided to the index frame 14. A guide rail 140 of which a longitudinal direction is the second direction 94 is provided within the index frame 14, and the index robot 120 may be provided to be movable along the guide rail 140. The index robot 120 includes a hand 122 on which the substrate W is placed. The hand 122 may be provided to move forward and backward, rotate around the third direction 96, and be movable along the third direction 96. The plurality of hands 122 is provided while being spaced apart from each other in the up and down direction, and is capable of independently moving forward and backward.

The treating module 20 includes a buffer unit 200, a transfer chamber 300, and a liquid treating chamber 400.

The buffer unit 200 provides a space in which the substrate W moved between the index module 10 and the transfer chamber 300 temporarily stays. The liquid treating chamber 400 performs a liquid treatment process of liquid-treating the substrate W by supplying a liquid onto the substrate W. The transfer chamber 300 transfers the substrate W between the buffer unit 200 and the liquid treating chamber 400.

The transfer chamber 300 may be provided so that a longitudinal direction thereof is the first direction 92. The buffer unit 200 may be disposed between the index module 10 and the transfer chamber 300. A plurality of liquid treating chambers 400 is provided. The liquid treating chamber 400 may be disposed on a side portion of the transfer chamber 300. The liquid treating chamber 400 and the transfer chamber 300 may be disposed in the second direction 94. The buffer unit 200 may be located at one end of the transfer chamber 300.

According to the example, the liquid treating chambers 400 are respectively disposed on opposite sides of the transfer chamber 300. At each of opposite sides of the transfer chamber 300, the liquid treating chambers 400 may be provided in an array of A×B (each of A and B is 1 or a natural number greater than 1) in the first direction 92 and the third direction 96.

The transfer chamber 300 includes a transfer robot 320. A guide rail 340 whose longitudinal direction is provided in the first direction 92 is provided within the transfer chamber 300, and the transfer robot 320 may be provided to be movable on the guide rail 340. The transfer robot 320 includes a hand 322 on which the substrate W is placed. The hand 322 may be provided to move forward and backward, rotate around the third direction 96, and be movable along the third direction 96. The plurality of hands 322 is provided while being spaced apart from each other in the vertical direction, and is capable of independently moving forward and backward.

The buffer unit 200 includes a plurality of buffers 220 on which the substrate W is placed. The buffers 220 may be disposed while being spaced apart from each other in the third direction 96. A front face 201 and a rear face 202 of the buffer unit 200 are opened. The front face 201 of the buffer unit 200 is a face facing the index module 10, and the rear face 202 of the buffer unit 200 is a face facing the transfer chamber 300. The index robot 120 may approach the inside of the buffer unit 200 through the front face 201 of the buffer unit 200, and the transfer robot 320 may approach the buffer unit 200 through the rear face 202 of the buffer unit 200.

The controller 2 controls the substrate processing apparatus 1. The controller 2 controls various components including a valve, a heater, and the like of the liquid supply unit 500 to be described below.

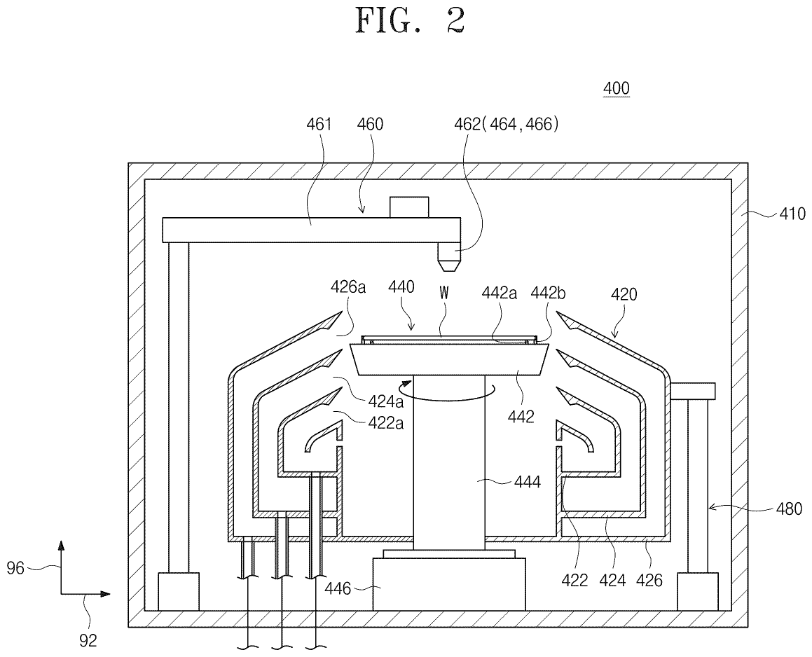

FIG. 2 is a diagram schematically illustrating the liquid treating chamber of FIG. 1 according to an exemplary embodiment.

Referring to FIG. 2, the liquid treating chamber 400 includes a housing 410, a cup 420, a support unit 440, a nozzle unit 460, and a lifting unit 480.

The housing 410 is provided in a generally rectangular parallelepiped shape. The cup 420, the support unit 440, the nozzle unit 460, and the lifting unit 480 are disposed within the housing 410.

The cup unit 420 has a treatment space 402 in which an upper portion is opened. The cup unit 420 includes an inner cup 422, an intermediate cup 424, and an outer cup 426. The inner cup 422, the intermediate cup 424, and the outer cup 426 each have recovery spaces for recovering a liquid used for processing the substrate W. The inner cup 422, the intermediate cup 424, and the outer cup 426 are each provided in a ring shape surrounding the support unit 440. When the liquid treatment process is performed, the treatment liquid scattered by rotation of the substrate W flows into the recovery spaces through the inlets 422a, 424a, and 426a of the inner cup 422, the intermediate cup 424, and the outer cup 426. According to the exemplary embodiment, the inner cup 422 is disposed to surround the support unit 440, the intermediate cup 424 is disposed to surround the inner cup 422, and the outer cup 426 is disposed to surround the intermediate cup 424. The intermediate cup inlet 424a through which the liquid flows into the intermediate cup 424 may be positioned above the inner cup inlet 422a through which the liquid flows into the inner cup 422, and the outer cup inlet 426a through which the liquid flows into the outer cup 426 may be positioned above the intermediate cup inlet 424a through which the liquid flows into the intermediate cup 424.

The support unit 440 supports the substrate W in the treatment space 402. The support unit 440 includes a spin chuck 442 and a drive shaft 444. An upper surface of the spin chuck 442 may be provided in a generally circular shape, and may have a diameter larger than a diameter of the substrate W. A chuck pin 442b is provided at an edge of the spin chuck 442. The chuck pin 442b is provided to protrude upward from the spin chuck 442. The chuck pin 442b supports a side portion of the substrate W so that the substrate W does not deviate from the support unit 440 when the substrate W is rotated. Also, a support pin 442a is provided to the spin chuck 442. The support pin 442a is provided with a top end protruding from the spin chuck 442 such that the substrate W is spaced a certain distance from the spin chuck 442. The support pin 442a is disposed closer to a center of the spin chuck 442 than the chuck pin 442b. The drive shaft 444 is driven by the driver 446, is connected to a center of a bottom surface of the substrate W, and rotates the spin chuck 442 with respect to its central axis.

The nozzle unit 460 supplies a treatment liquid onto the substrate W supported on the support unit 440. The treatment liquid may be provided in a plurality of types, and may be sequentially supplied onto the substrate W. The nozzle unit 460 includes a support frame 470, an arm 472, a first nozzle 462, a second nozzle 464, a third nozzle 466, and a nozzle driver 468.

The first nozzle 462 supplies a first treatment liquid onto the substrate W. The second nozzle 464 supplies a second treatment liquid onto the substrate W. The third nozzle 466 supplies the third treatment liquid onto the substrate W. The first treatment liquid, the second treatment liquid, and the third treatment liquid are different types of treatment liquids. The first treatment liquid, the second treatment liquid, and the third treatment liquid may be an acidic component, an alkali component, or a neutral component. For example, the first treatment liquid, the second treatment liquid, and the third treatment liquid may be an acid component, such as sulfuric acid, hydrofluoric acid, phosphoric acid, or hydrochloric acid, or may be an alkali component, such as ammonia, or water.

Meanwhile, a nozzle unit 460 for supplying another type of treatment liquid may be further provided. For example, the nozzle unit 460 may further include a nozzle for supplying an organic solvent, such as isopropyl alcohol (IPA).

The lifting unit 480 adjusts a relative height between the cup 420 and the support unit 440. According to an example, the lifting unit 480 moves the cup 420 in the up and down direction. By the up and down movement of the cup 420, a relative height between the cup 420 and the substrate W is changed. Accordingly, the recovery containers 422, 424, and 426 for recovering the treatment liquid are changed according to the type of liquid supplied to the substrate W, and thus the treatment liquids may be separated and recovered. Unlike the description, the cup 420 may be fixedly installed, and the lifting unit 480 may move the support unit 440 in the vertical direction.

The treatment liquid is supplied to the nozzles 462, 464, and 466 by the liquid supply unit 500. Hereinafter, as an example, a mixed solution of sulfuric acid and hydrogen peroxide water is used as the treatment liquid.

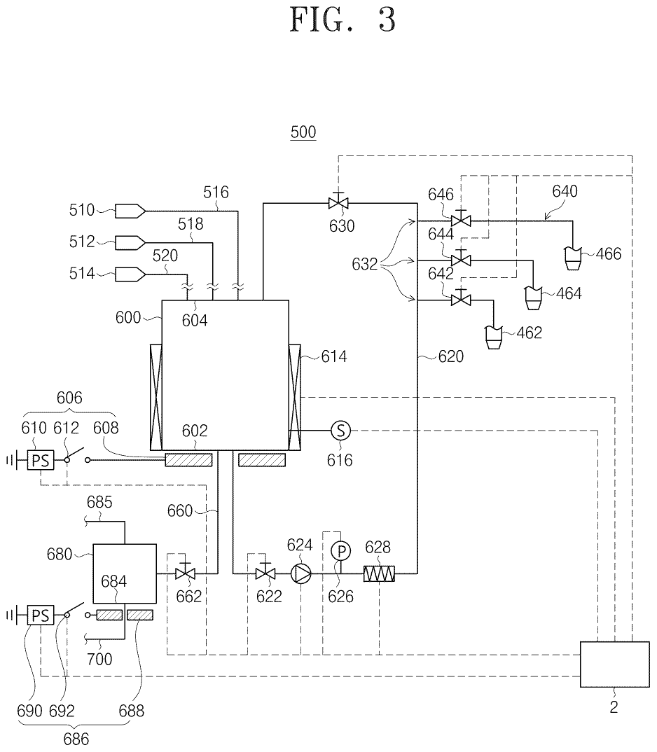

FIG. 3 is a diagram schematically illustrating the configuration of the liquid supply unit for supplying a treatment liquid to a nozzle of the liquid treating chamber.

Referring to FIG. 3, the liquid supply unit 500 has a supply tank 600, a circulation line 620, a liquid supply line 640, a drain box 680, and a drain line 660.

The supply tank 600 stores the treatment liquid supplied to the liquid treating chamber 400. The treatment liquid is mixed in the supply tank 600, and the temperature and concentration of the treatment liquid are adjusted. The supply tank 600 is generally provided in a cylindrical shape. A space in which a treatment liquid may be stored is formed in the supply tank 600. A heater 614, a temperature sensor (not illustrated), and a first stirrer 606 are installed in the supply tank 600. The heater 614 heats the treatment liquid in the supply tank 600 to maintain the treatment liquid at a constant temperature. According to an exemplary embodiment, the heater 614 may be installed on a side surface of the supply tank 600.

The first stirrer 606 mixes liquids supplied to the supply tank 600 from liquid supply sources 510, 512, and 514, and makes the liquid flow in the supply tank 600 to mix the liquids. The first stirrer 606 is installed outside the supply tank 600. According to the exemplary embodiment, the first stirrer 606 is installed below the supply tank 600. As the first stirrer 606, a magnetic stirrer is used. The magnetic stirrer includes an electromagnet 608, a power supply device 610, and a switch 612. The electromagnet 608 is disposed outside the supply tank 600. For example, the electromagnet 608 may be disposed below a lower end 602 of the supply tank 600. A plurality of electromagnets 608 are provided. The power supply device 610 applies a current to the electromagnet 608 to form magnetic force in the supply tank 600, thereby providing the flow pressure to the treatment liquid in the supply tank 600. According to the exemplary embodiment, the first stirrer 606 may be provided as a heating type magnetic stirrer for stirring the treatment liquid in the supply tank 600 and simultaneously heating the treatment liquid.

The circulation line 620 is connected to the supply tank 600. The treatment liquid stored in the supply tank 600 is circulated through the circulation line 620. In the circulation line 620, an inlet end is connected to the lower end 602 of the supply tank 600, and an outlet end is connected to an upper wall 604 of the supply tank 600. The outlet end may be provided to be immersed in the treatment liquid filled in the supply tank 600. A valve 622, a pump 624, a pressure sensor 626, and a heater 628 are installed in the circulation line 620. In addition, various other components in addition to the above-described components may be further installed in the circulation line 620. For example, a filter may be further installed in the circulation line 620.

The valves 622 and 630 open and close the circulation line 620. A plurality of valves 622 and 630 is installed in the circulation line 620. Based on a branch point 632 at which the liquid supply line 640 branches from the circulation line 620, the valve 622 is installed in the circulation line 620 upstream from the branch point 632. Additionally, the valve 630 may be installed in the circulation line 620 downstream from the branch point 632.

The pump 624 applies a flow pressure to allow the treatment liquid to flow through the circulation line 620. The treatment liquid flows along the circulation line 620 by the flow pressure applied from the pump 624.

The pressure sensor 626 measures the flow pressure of the treatment liquid in the circulation line 620 in real time.

The heater 628 heats the treatment liquid flowing through the circulation line 620. The heater 628 heats the treatment liquid so that the treatment liquid supplied to the liquid treating chamber 400 maintains a set temperature.

The valve 622, the pump 624, the pressure sensor 626, and the heater 628 are sequentially arranged in a direction from the upstream of the circulation line 620 toward the downstream. The valve 622, the pump 624, and the heater 628 are installed in the circulation line upstream from the branch point.

The liquid supply line 640 branches from the circulation line 620. When the treatment liquid is supplied to a plurality of liquid treating chambers 400, the liquid supply line 640 is provided as many as the number of liquid treating chambers 400. Valves 642, 644, and 646 are installed on the liquid supply lines 640, respectively. The valves 642, 644, and 646 are opening/closing valves. In addition, a flow rate control valve may be further installed in each liquid supply line 640.

A drain line 660 is connected to the supply tank 600. When a treatment liquid is replaced in the supply tank 600, the treatment liquid in the supply tank 600 is discharged from the supply tank 600 through the drain line 660. An opening/closing valve 662 is installed on the drain line 660. The drain line 660 is connected to the drain box 680.

The drain box 680 stores the treatment liquid discharged from the supply tank 600 for a predetermined time. While the treatment liquid is stored in the drain box 680, the high-temperature treatment liquid is cooled to room temperature. Furthermore, a diluent supply line 685 for supplying a diluent into the drain box 680 is connected to the drain box 680. The diluent may be water. The diluent dilutes the concentration of the treatment liquid and also cools the high-temperature treatment liquid. A discharge pipe 700 is connected to a lower portion 684 of the drain box 680. The treatment liquid is discharged to the outside through the discharge pipe 700.

A second stirrer 686 is installed in the drain box 680. The second stirrer 686 is installed outside the drain box 680. According to the exemplary embodiment, the second stirrer 686 is installed under the drain box 680. According to the exemplary embodiment, the second stirrer 686 may be provided as a magnetic stirrer. The second stirrer 686 according to the exemplary embodiment includes an electromagnet 688, a power supply 690, and a switch 692. The second stirrer 686 may operate in the same principle as the first stirrer 606.

Hereinafter, a method of processing a substrate using the liquid supply unit of FIG. 3 will be described.

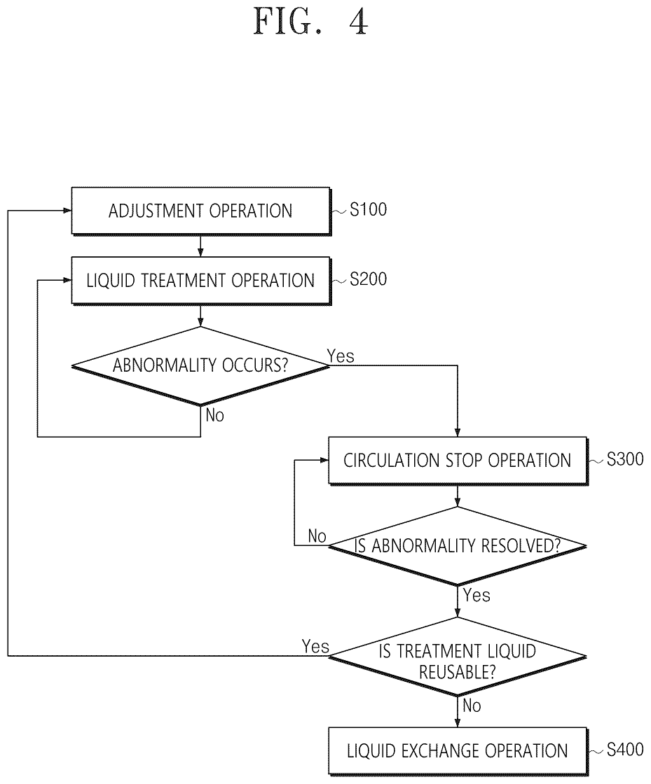

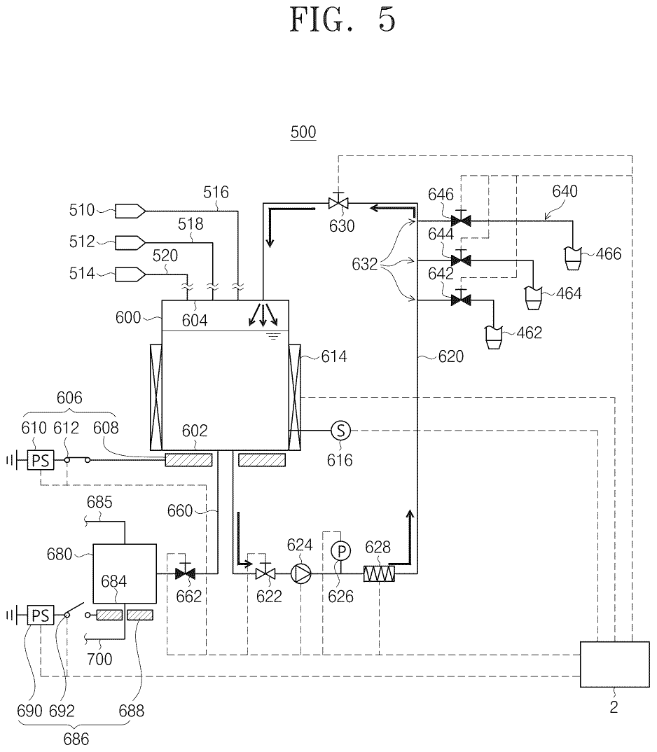

FIG. 4 is a flowchart schematically illustrating a process of supplying a treatment liquid by the liquid supply unit of FIG. 3. FIGS. 5 to 8 are diagrams schematically illustrating the liquid supply unit in an adjustment operation, a liquid treatment operation, a circulation stop operation, and a liquid exchange operation of FIG. 4, respectively.

For the valves illustrated in each drawing, the valve of which the inside is not filled represents the valve in the open state, and the valve of which the inside is filled represents the valve in the closed state.

The treatment liquid treatment process includes an adjustment operation S100, a liquid treatment operation S200, a circulation stop operation S300, and a liquid exchange operation S400.

The substrate processing apparatus in each operation will be described with reference to FIGS. 4 to 8.

In the adjustment operation S100, sulfuric acid, hydrogen peroxide water, and water supplied to the supply tank 600 are mixed to generate a treatment liquid, and the temperature and the concentration of the treatment liquid are adjusted to be a set temperature and a set concentration suitable for processing the substrate W. In the adjustment operation S100, the treatment liquid is heated by the heater 614 installed in the supply tank 600 and the heater 628 installed in the circulation line 620.

Referring to FIG. 5, the liquid constituting the treatment liquid is supplied to the supply tank 600 from each of the liquid supply sources 510, 512, and 514 through inflow lines 516, 518, and 520. In the adjustment operation S100, the treatment liquid is circulated through the circulation line 620. All of the valves 622 and 630 installed in the circulation line 620 are opened. The valves 642, 644, and 646 installed in the other liquid supply lines 640 and the valve 662 installed in the drain line 660 are closed. The treatment liquid flows from the supply tank 600 through the inlet end of the circulation line 620 and then enters the supply tank 600 again through the outlet end of the circulation line 620. Also, the treatment liquid supplied into the supply tank 600 in the adjustment operation S100 is mixed by the first stirrer 606. In this case, the switch 612 connected to the first stirrer 606 is turned on. Accordingly, a current is applied to the first stirrer 606, and a flow is generated in the treatment liquid in the supply tank 600 to mix the treatment liquid in the supply tank 600. That is, in the adjustment operation S100, the circulation of the treatment liquid through the circulation line 620 and the mixing by the flow of the treatment liquid in the supply tank 600 by the first stirrer 606 are performed together.

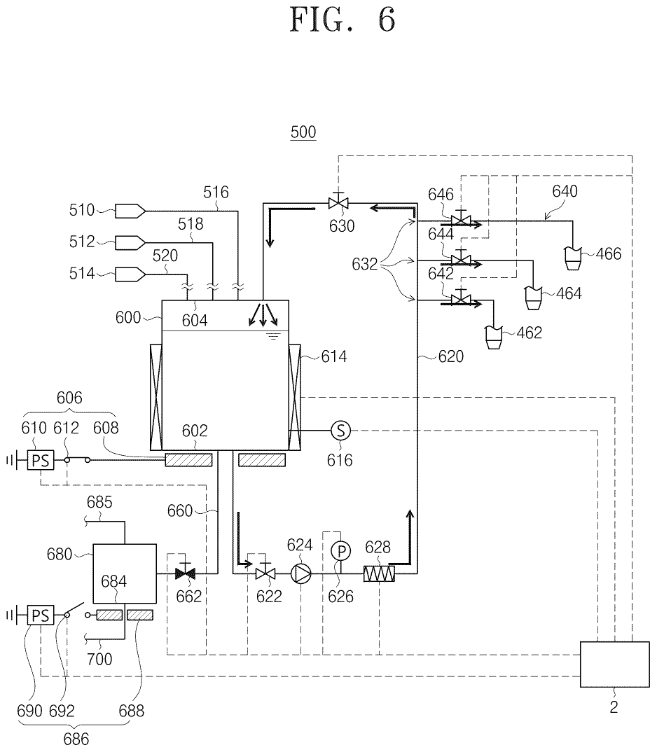

After the adjustment operation S100 is performed, the liquid treatment operation S200 is performed. The liquid treatment operation S200 is an operation of liquid-treating the substrate W by supplying the treatment liquid onto the substrate W. Referring to FIG. 6, after the treatment liquid becomes suitable for the treatment of the substrate W, the treatment liquid is supplied to the nozzles 462, 464, and 466. The valves 642, 644, and 646 installed on the liquid supply line 640 are opened for the supply of the treatment liquid. All of the valves 642, 644, and 646 may be opened, or only a part thereof may be selectively opened. The valves 622 and 630 installed on the circulation line 620 are maintained to be opened, and the valve 662 installed on the drain line 660 is maintained to be closed.

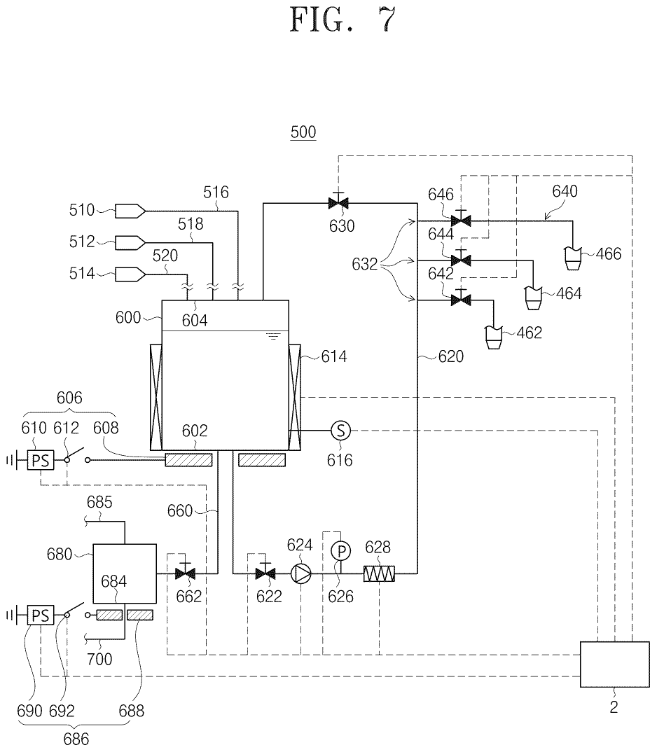

In this process, whether an abnormality occurs in the liquid supply unit 500 is monitored. When the abnormality does not occur, the liquid treatment operation S200 is continuously performed. However, when an abnormality occurs, the circulation stop operation S300 is performed. In the circulation stop operation S300, the liquid treatment operation S200 is stopped, and the operation of the liquid supply unit 500 is also stopped. Referring to FIG. 7, in the circulation stop operation S300, the operation of the pump 624 is stopped. Accordingly, circulation of the treatment liquid is stopped. In addition, the valves 622 and 630 installed on the circulation line 620, the valves 642, 644, and 646 installed on the liquid supply line 640, and the valve 62 installed on the drain line 660 are closed. The heater 614 installed in the supply tank 600 and the heater 628 installed on the circulation line 620 stop operating, and the switch 612 of the first stirrer 606 and the switch 692 of the second stirrer 686 also become the “OFF” state. As the circulation is stopped, the treatment liquid is stagnated in the supply tank 600. As the treatment liquid is stagnated in the supply tank 600 for a long time, aggregation of the treatment liquid occurs. As a result, the treatment liquid aggregated in the lower portion of the supply tank 600 is precipitated, and these precipitates become particles.

Thereafter, when the abnormality of the liquid supply unit 500 is not resolved, the circulation stop operation S300 is maintained. When the abnormality of the liquid supply unit 500 is resolved, whether the treatment liquid can be reused is determined. In the exemplary embodiment, the determination of whether to reuse the treatment liquid may be performed by measuring the amount of particles by the sensor 616 installed in the supply tank 600. When the amount of particles formed in the supply tank 600 is lower than a set value, it is determined that the treatment liquid can be reused, and when the amount of particles is higher than the set value, it is determined that the treatment liquid cannot be reused.

When the treatment liquid can be reused, the adjustment operation S100 is performed again.

As illustrated in FIG. 5 above, the valves 622 and 630 installed on the circulation line 620 are opened, and circulation of the treatment liquid is resumed. The operation of the heater 614 installed in the supply tank 600 and the heater 628 installed on the circulation line 620 are resumed, so that the treatment liquid is heated while being circulated. Also, the switch 612 connecting the electromagnet 608 of the first stirrer 606 with the power supply device 610 is turned on. Accordingly, a current is applied to the electromagnet 608 so that the treatment liquid flows. In this case, the first stirrer 606 may be controlled to change the flow speed of the treatment liquid in the supply tank 600. In the exemplary embodiment, the first stirrer 606 may be controlled so that the treatment liquid flows faster as the difference between the set temperature and the temperature of the treatment liquid in the adjustment operation S100 increases. In addition, the first stirrer 606 may be controlled so that the treatment liquid flows faster as the temperature difference between the treatment liquids at different points in the supply tank 600 increases. Through this, the time required to adjust the treatment liquid reused after the circulation stop operation S300 to be in a state necessary for the process may be reduced.

When the treatment liquid cannot be reused, the liquid exchange operation S400 is performed. In the liquid exchange operation S400, the treatment liquid in the supply tank 600 is discharged, and the inside of the supply tank 600 is filled with a new treatment liquid.

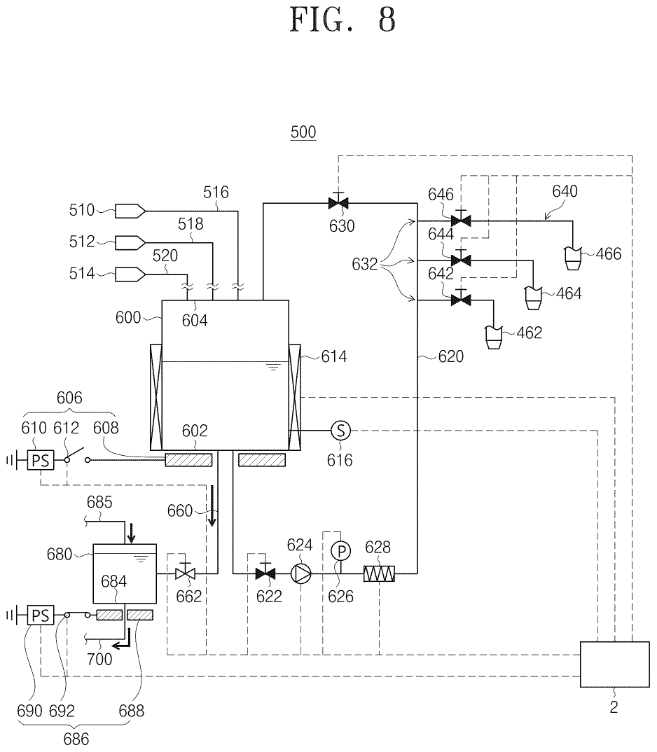

Referring to FIG. 8, in the liquid exchange operation, the valve 662 installed on the drain line 660 is opened, and the valves 622 and 630 installed on the circulation line 620 and the valves 642, 644, and 646 installed on the liquid supply line 640 are maintained to be closed. Accordingly, the treatment liquid in the supply tank 600 flows to the drain box 680 through the drain line 660. The treatment liquid flows into the drain box 680 in a high temperature state. Also, the diluent flows into the drain box 680 from the diluent supply line 685. Accordingly, the temperature and the concentration of the treatment liquid are lowered. The switch 692 of the second stirrer 686 installed in the drain box 680 is in the “ON” state. As the second stirrer 686 is operated, the treatment liquid in the drain box 680 flows, and the diluent and the treatment liquid are quickly mixed in the drain box 680. Accordingly, the treatment liquid and the diluent are uniformly mixed over the entire area of the drain box 680 so that the temperature and concentration are rapidly and uniformly lowered. Accordingly, it is possible to shorten the time required for disposal of the treatment liquid.

Hereinafter, various modified examples of the substrate processing apparatus and the substrate processing method using the same according to the present invention will be described.

In the above-described exemplary embodiment, it has been described that the operation of the first stirrer 606 is stopped in the circulation stop operation S300. However, this is illustrative and the present invention is not limited thereto. The first stirrer 606 may also be operated in the circulation stop operation S300. In this case, the precipitation of the treatment liquid is minimized by allowing the treatment liquid to flow in the supply tank 600 even in the circulation stop operation S300. Even when the operation of the liquid supply unit 500 is stopped for a long time, a particle generation rate due to the aggregation of the treatment liquid decreases. Therefore, since the treatment liquid in the supply tank 600 may be reused after the abnormality is resolved, waste of the treatment liquid may be prevented.

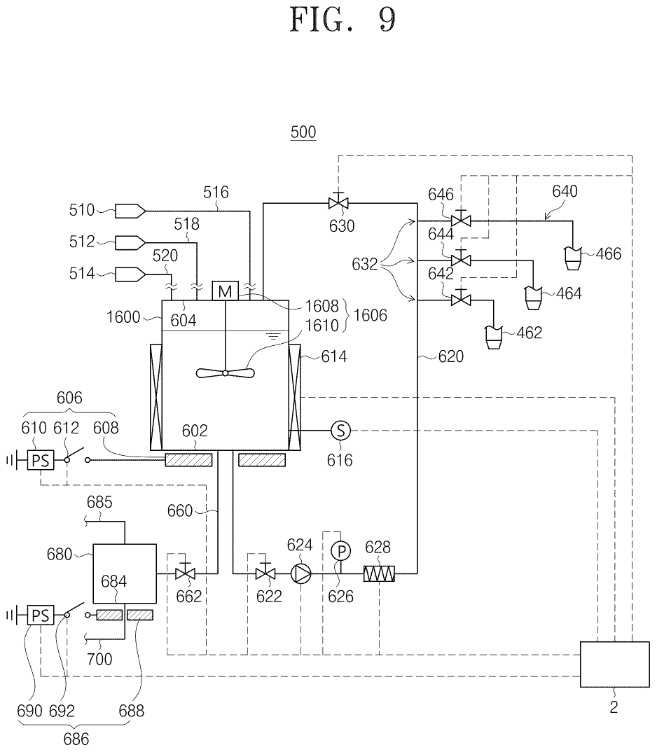

In the above exemplary embodiment, the present invention has been described based on the case where the first stirrer 606 installed in the supply tank 600 is a magnetic stirrer. However, this is illustrative, and the first stirrer 1606 may be provided as a mechanical stirrer as illustrated in FIG. 9. In this case, the first stirrer 1606 may have a blade 1610 rotated by a motor 1608 in the supply tank 1600.

In the above-described exemplary embodiment, the present invention has been described based on the case where each of the first stirrer 606 installed in the supply tank 600 and the second stirrer 686 installed in the drain box 680 is the magnetic stirrer. However, the first stirrer 606 and the second stirrer 686 do not necessarily have to be used independently by a magnetic stirrer, and may be used together with a mechanical stirrer depending on a type of process.

In the above-described exemplary embodiment, the present invention has been described based on the case where in the adjustment operation S100, the flow rate of the treatment liquid is controlled according to the difference between the set temperature and the temperature of the treatment liquid. However, this is exemplary, and the rotation speed of the treatment liquid may be controlled in various ways.

The specification described above provides examples of the present disclosure. Further, the description provides exemplary embodiments of the present disclosure and the present disclosure may be used in other various combinations, changes, and environments. That is, the present disclosure may be changed or modified within the scope of the present disclosure described herein, within a range equivalent to the description, and/or within the knowledge or technology in the related art. The embodiment shows an optimum state for achieving the spirit of the present disclosure and may be changed in various ways for the detailed application fields and use of the present disclosure. Therefore, the detailed description of the present disclosure is not intended to limit the present disclosure in the embodiment. Further, the claims should be construed as including other embodiments.

1.-9. (canceled)

10. A method of processing a substrate, the method comprising:
an adjustment operation of adjusting a temperature and a concentration of a treatment liquid stored in a supply tank; and
a liquid treatment operation of supplying the temperature and concentration adjusted treatment liquid to a liquid treating chamber through a liquid supply line branching from the circulation line, after the adjustment operation,
wherein in the adjustment operation, the treatment liquid flows by a first stirrer installed in the supply tank while the treatment liquid is circulated.

11. The method of claim 10, wherein in the adjustment operation, the treatment liquid is heated using a heater installed in the supply tank while circulating the treatment liquid.

12. The method of claim 10, further comprising:
a circulation stop operation of stopping operation when an abnormality occurs in a liquid supply unit including the supply tank, the circulation line, and the liquid supply line,
wherein in the circulation stop operation, the treatment liquid in the supply tank flows using the first stirrer installed in the supply tank.

13. The method of claim 11, wherein in the adjustment operation, as a difference between a set temperature and a temperature of the treatment liquid increases, a flow rate of the treatment liquid in the supply tank increases.

14. The method of claim 10, further comprising:
a circulation stop operation of stopping operation when an abnormality occurs in a liquid supply unit including the supply tank, the circulation line, and the liquid supply line,
wherein when the abnormality of the liquid supply unit is resolved and the treatment liquid is reusable, the adjustment operation is performed again.

15. The method of claim 14, wherein the first stirrer provides flow pressure to the treatment liquid by magnetic force.

16. The method of claim 10, further comprising:
a liquid exchange operation of exchanging the treatment liquid in the supply tank, the liquid exchange operation being performed when the treatment liquid is not reusable after the circulation stop operation.

17. The method of claim 16, wherein in the liquid exchange operation, the treatment liquid in the supply tank is discharged to a drain box through a drain line, and the treatment liquid in the drain box flows by a second stirrer installed in the drain box.

18. The method of claim 17, wherein the second stirrer provides flow pressure to the treatment liquid by magnetic force.

19. The method of claim 10, wherein the treatment liquid is a mixture of sulfuric acid (H₂SO₄), hydrogen peroxide (H₂O₂), and pure water (H₂O).

20. (canceled)
